(19) United States
(12) Patent Application Publication
(10) Pub. No.: US 2026/0060041 A1
(43) Pub. Date: Feb. 26, 2026

(54) DYNAMIC RANDOM-ACCESS MEMORY (DRAM) TEST PAD ARRANGEMENT METHOD FOR A DRAM CELL REPAIR TEST ON THREE-DIMENSIONAL (3D) STACKED DRAM

(71) Applicant: QUALCOMM Incorporated, San Diego, CA (US)

(72) Inventors: Woo Tag KANG, San Diego, CA (US); Mustafa BADAROGLU, San Diego, CA (US); Jihong CHOI, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/205,781

(22) Filed: May 12, 2025

Related U.S. Application Data
(60) Provisional application No. 63/687,226, filed on Aug. 26, 2024.

(51) Int. Cl. H01L 21/66; H01L 25/065; H10B 12/00; H10B 80/00

(52) U.S. Cl. CPC H01L 22/32; H01L 22/34; H01L 25/0657; H10B 12/02; H10B 12/48; H10B 12/50; H10B 80/00

(57) ABSTRACT

A memory wafer is described. The memory wafer includes memory dies on the memory wafer. Additionally, the memory wafer includes wire connections at least partially within one of the memory dies. The wire connections are configured to couple to memory test and repair pads along at least one scribe line between the one of the memory dies and adjacent memory dies.

### CROSS-REFERENCE TO RELATED APPLICATION

The present application claims the benefit of U.S. Provisional Ser. No. 63/687,226 , filed Aug. 26, 2024, and titled “DYNAMIC RANDOM-ACCESS MEMORY (DRAM) TEST PAD ARRANGEMENT METHOD FOR A DRAM CELL REPAIR TEST ON THREE-DIMENSIONAL (3D) STACKED DRAM,” the disclosure of which is expressly incorporated by reference herein in its entirety.

### BACKGROUND

### Field

Aspects of the present disclosure relate to semiconductor memory devices and, more particularly, to a dynamic random-access memory (DRAM) test pad arrangement method for a DRAM cell repair test on three-dimensional (3D) stacked DRAM.

### Background

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a higher-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D) stacked memories composed of high-bandwidth memory (HBM) DRAM provide advantages in performance and power for memory-demanding workloads. Single stacked DRAM yield is a significant factor in these 3D stacked memories. For example, a single DRAM yield of 97% is reduced to a stacked yield of less than 78% in an integration scheme that utilizes low-cost wafer-to-wafer stacking of eight wafers. Due to this limited yield, DRAM vendors prefer slow and costly die-to-die stacking for implementing high-bandwidth memory (HBM) solutions. Additionally, conventional repair techniques (e.g., redundant row, column, and error correction code (ECC)) fail to increase the single DRAM wafer yield to a desired level. A memory test pad arrangement method for a memory cell repair test on 3D stacked memory, is desired.

### SUMMARY

A memory wafer is described. The memory wafer includes memory dies on the memory wafer. Additionally, the memory wafer includes wire connections at least partially within one of the memory dies. The wire connections are configured to couple to memory test and repair pads along at least one scribe line between the one of the memory dies and adjacent memory dies.

A memory die is described. The memory die includes a memory cell array. Additionally, the memory die includes wire connections to couple data DQ output pads and command connections of the memory cell array. Each of the wire connections includes a wire stub portion exposed along an edge of the memory die.

A method for a memory cell repair test during fabrication is described. The method includes probing a memory wafer using memory test and repair pads on scribe lines of the memory wafer to perform a test on memory dies residing on the memory wafer. The method also includes verifying the memory wafer based on a result of the test. The method further includes performing wafer-to-wafer bonding of the memory wafer, if verified, and one or more verified memory wafers to form a memory wafer stack.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a test pad arrangement for memory cell testing and repair in three-dimensional (3D) stacked memory, in accordance with aspects of the present disclosure.

FIG. 2A is a block diagram illustrating a high-bandwidth three-dimensional (3D) stacked memory chip fabricated from unverified wafers.

FIG. 2B is a layout view of a conventional wafer quality assessment test.

FIG. 3 illustrates a layout view of a memory test pad arrangement for memory cell testing and repair of the high-bandwidth three-dimensional (3D) stacked memory chip of FIG. 2A, according to various aspects of the present disclosure.

FIGS. 4A and 4B illustrate layout views of a memory test pad arrangement for memory cell testing and repair, according to various aspects of the present disclosure.

FIG. 5 illustrates a process of forming dynamic random-access memory (DRAM) cell test and repair pads in three-dimensional (3D) stacked DRAM for improved yield, according to various aspects of the present disclosure.

FIG. 6 is a process flow diagram illustrating a method for forming dynamic random-access memory (DRAM) cell test pads on scribe lines of a DRAM wafer, according to various aspects of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of a semiconductor component, such as the vertical bank redundancy in three-dimensional (3D) stacked dynamic random-access memory (DRAM) for improved yield disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR. ” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to. ” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die”may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a higher-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D) stacked memories composed of high-bandwidth memory (HBM) DRAM provide advantages in performance and power for memory-demanding workloads. Single stacked DRAM yield is a significant factor in these 3D stacked memories. For example, a single DRAM yield of 97% is reduced to a stacked yield of less than 78% in an integration scheme that utilizes low-cost wafer-to-wafer stacking of eight wafers. Due to this limited yield, DRAM vendors prefer slow and costly die-to-die stacking for implementing HBM solutions.

Three-dimensional (3D) memory stacking involves a base logic die that supports stacking of memory dies (e.g., DRAM dies) on the base logic die. In the 3D DRAM stack as well as the base logic die, DRAM cell testing as well as DRAM cell repair through normal DRAM test pads on the actual DRAM die is challenging. DRAM cell testing and cell repair is complicated by the intricacy of a DRAM floor plan, which involves many through silicon via (TSV) connections in the 3D DRAM stack. This limited testing fails to perform low yield DRAM wafer monitoring, resulting in the stacking of low yield wafer during DRAM wafer-to-wafer hybrid bonding. This limited testing causes a significant drop in 3D DRAM yield and significantly increases DRAM cost. Additionally, normal DRAM test pads affect the DRAM wafer bonding yield. A memory test pad arrangement method for a memory cell repair test on 3D stacked memory, is desired.

Various aspects of the present disclosure are directed to a DRAM pad arrangement on a DRAM wafer scribe line for performing DRAM cell testing and DRAM cell repair. In some implementations, DRAM cell test pads are placed on the scribe line of a DRAM wafer to avoid the complexity of the DRAM floor plan, which involves many intricate TSV connections. Various aspects of the present disclosure improve DRAM yield, by pre-forming DRAM cell test/repair on the DRAM wafer before the 3D DRAM wafer bonding process. According to various aspects of the present disclosure, placement of DRAM cell test pads on the scribe line DRAM wafer enables wafer probe testing for DRAM wafer yield evaluation by rejecting deficient DRAM wafers. Hence, the overall manufacturing process can be made more efficient by rejecting deficient DRAM wafers sooner. Additionally, a die test may involve statistically selecting DRAM dies among DRAM dies on the DRAM wafer to assess DRAM wafer yield, which saves test time and cost.

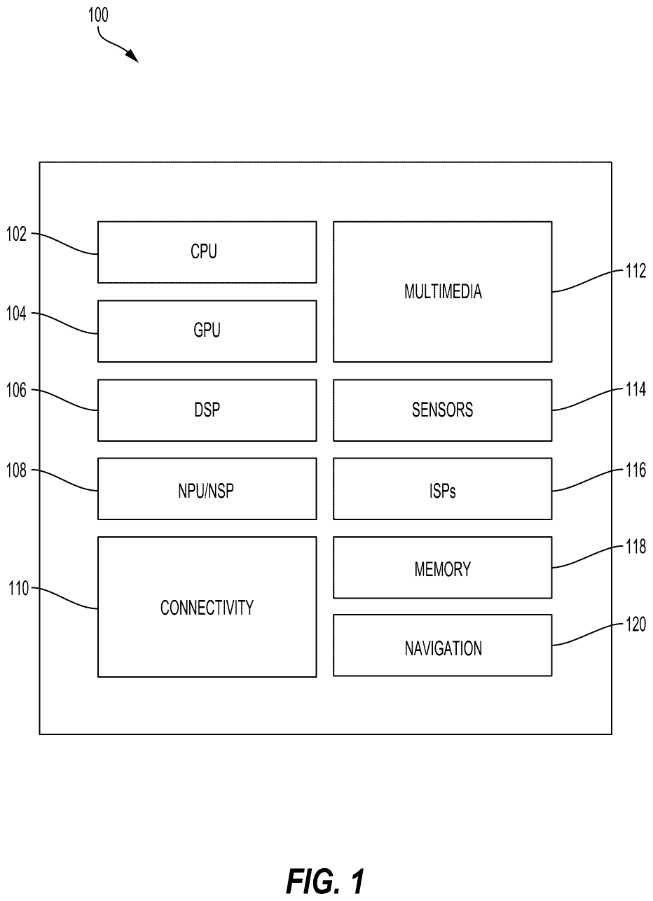

FIG. 1 illustrates an example implementation of a host system-on-chip (SoC) 100, which includes a test pad arrangement for memory cell testing and repair in three-dimensional (3D) stacked memory, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

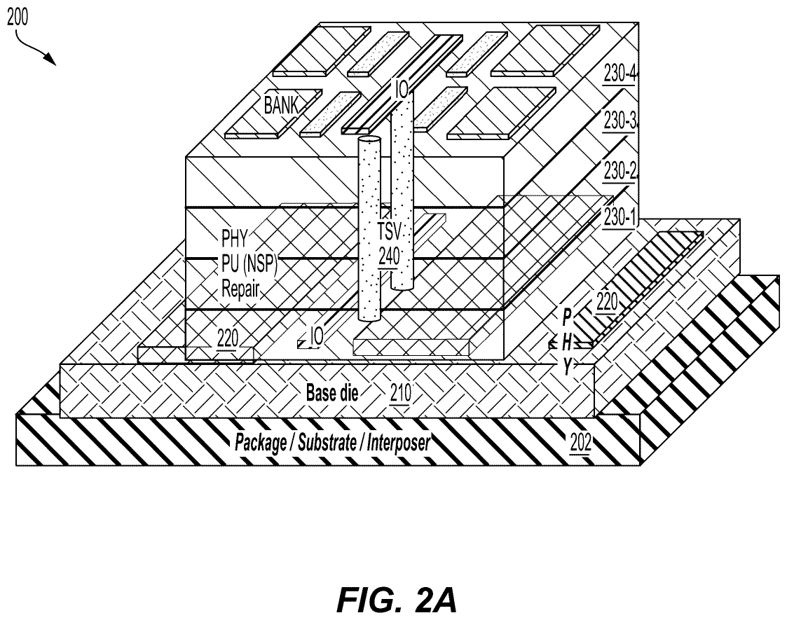

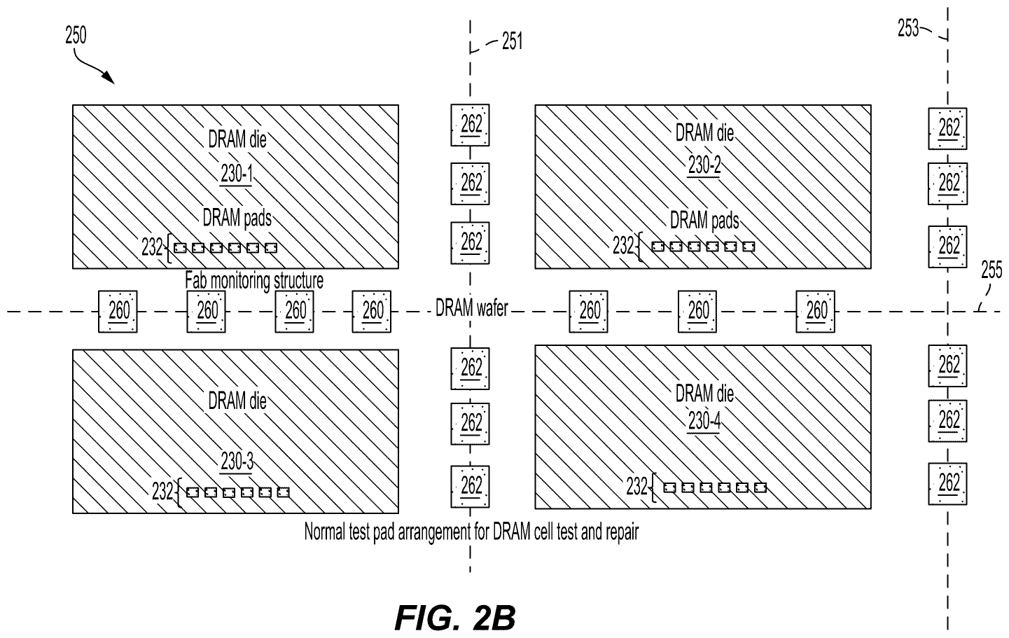

FIG. 2A is a block diagram illustrating a high-bandwidth three-dimensional (3D) stacked memory chip fabricated from unverified wafers. As shown in FIG. 2, the high-bandwidth 3D stacked memory chip 200 includes a base die 210 (e.g., a first die) that is supported by a package substrate 202 (e.g., interposer). In various aspects of the present disclosure, the base die 210 supports stacking of memory dies 230 (e.g., dynamic random-access memory (DRAM) dies) on the base die 210. The number of memory dies stacked on the base die 210 varies in different implementations. In this example, four (4) memory dies 230 (230-1, 230-2, 230-3, 230-4) are arranged using a back-to-face stacking of DRAM dies on the base die 210. In another implementation, the base die 210 supports a stack of twelve (12) DRAM dies.

In various aspects of the present disclosure, the memory dies 230 include memory banks (BANK) and an input/output (IO) block that utilize signal through silicon vias (TSVs) 240 extending through the memory dies 230 (e.g., second die) and landing on the base die 210. As shown in FIG. 2, the signal TSVs 240 provide signal transmission between the memory dies 230 and a physical layer (PHY) 220 of the base die 210. In this example, a processing unit (PU) (e.g., a neural signal processor (NSP)) may be implemented on the base die 210 in combination with the PHY 220, including a PHY 220 to a system-on-chip (e.g., SoC 100). Additionally, the high-bandwidth 3D stacked memory chip 200 includes DRAM power TSVs (not shown) between the memory banks and the package substrate 202. FIG. 2A illustrates two (2) signal TSVs 240 to avoid obscuring the view of the drawing; however, one of skill in the art can readily recognize that there can be more TSVs in the stack of memory dies 230 and/or TSVs at other locations within the stack of memory dies 230.

The manufacture of electrical circuits on semiconductor wafers (e.g., DRAM wafers) incorporates circuit testing at several stages of the fabrication process. A final test at the wafer level is usually the most important as it affects the yield of the process as well as the additional cost of further processing for defective products. The usual method of wafer testing utilizes probes that contact the metal surface pads of a wafer. These surface pads are connected to the semiconductor circuits. The probes in turn are connected to highly sophisticated test circuitry that provides electrical signals to the circuits and analyzes their response. This process is important for testing memory, such as the high-bandwidth 3D stacked memory chip 200 FIG. 2A.

FIG. 2B is a layout view 250 of a conventional wafer quality assessment test. As shown in FIG. 2B, the layout view 350 of a DRAM wafer illustrates the DRAM dies 230 (e.g., 230-1, 230-2, 230-3, 230-4) between a first vertical scribe line 251, a second vertical scribe line 253, and a horizontal scribe line 255. Additionally, a horizontal fabrication monitoring structure 260 and a vertical fabrication monitoring structure 262 are shown adjacent to the first vertical scribe line 251 and the second vertical scribe line 253. As noted, during fabrication, conventional DRAM cell testing is performed through normal DRAM test pads 232 on the DRAM die 230, along with DRAM wafer acceptance test (WAT) testing using the horizontal fabrication monitoring structure 260 and/or the vertical fabrication monitoring structure 262. Unfortunately, this process is complicated due to the intricacy of the DRAM floor plan, which involves many through silicon via (TSV) connections in the 3D DRAM stack.

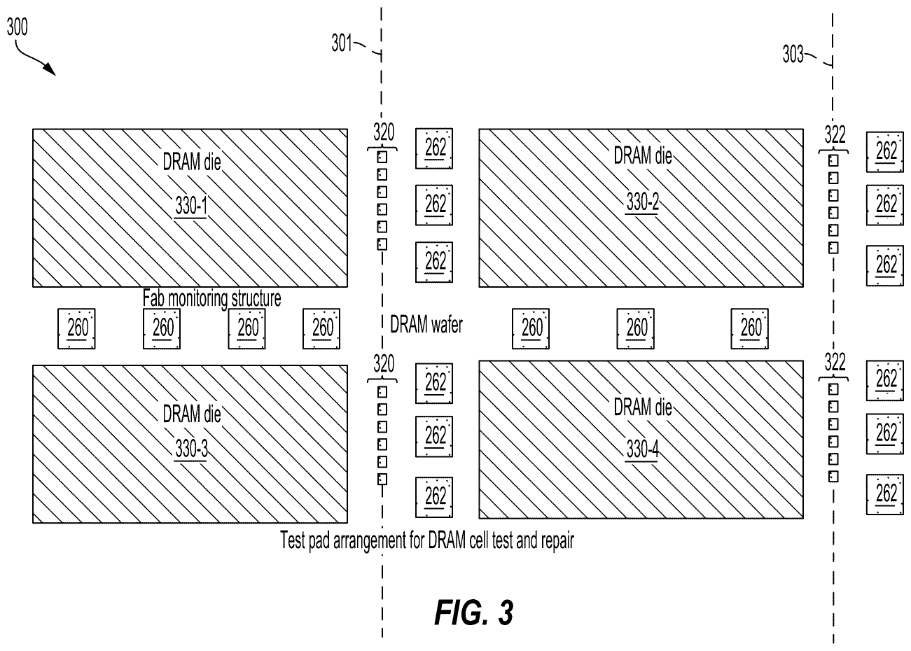

Referring again to FIG. 2A, the base die 210 supports 3D stacking of the memory dies 230 (e.g., DRAM dies) on the base die 210. During fabrication, DRAM cell testing as well as DRAM cell repair through normal DRAM test pads 232 on the actual DRAM wafer is challenging. DRAM cell testing and cell repair is complicated by the intricacy of the DRAM floor plan, which involves many TSV connections in the 3D DRAM stack. Additionally, normal DRAM test pads 232 can adversely affect the DRAM wafer bonding yield. A memory test pad arrangement method for a memory cell repair test on 3D stacked memory is shown, for example, in FIGS. 3-5.

FIG. 3 illustrates a layout view 300 of a memory test pad arrangement for memory cell testing and repair of the high-bandwidth three-dimensional (3D) stacked memory chip 200 of FIG. 2A, according to various aspects of the present disclosure. FIG. 3 illustrates the layout view 300 of a dynamic random-access memory (DRAM) test pad arrangement for DRAM cell testing and repair in a scribe line of a DRAM wafer, according to various aspects of the present disclosure.

As shown in FIG. 3, the layout view 300 of a DRAM wafer illustrates DRAM dies 330 (e.g., a first memory die 330-1, a second memory die 330-2, a third memory die 330-3, and a fourth memory die 330-4) between a first vertical scribe line 301 and a second vertical scribe line 303. Additionally, the horizontal fabrication monitoring structure 260 and the vertical fabrication monitoring structure 262 are shown adjacent to the first vertical scribe line 301 and the second vertical scribe line 303. As noted, during fabrication, conventional DRAM cell testing is performed through normal DRAM test pads 232 on the actual DRAM die 230, along with the WAT testing using the horizontal fabrication monitoring structure 260 and/or the vertical fabrication monitoring structure 262, as shown in FIG. 2B. Unfortunately, this process is complicated due to the intricacy of the DRAM floor plan, which involves many through silicon via (TSV) connections in the 3D DRAM stack.

As shown in FIG. 3, a DRAM test pad arrangement is provided on a DRAM wafer scribe line for performing DRAM cell testing and DRAM cell repair, according to various aspects of the present disclosure. In some implementations, first DRAM cell test pads 320 are placed on the first vertical scribe line 301, and the second DRAM cell test pads 322 are placed on the second vertical scribe line 303 of the DRAM wafer to avoid the complexity of the DRAM floor plan, which involves many intricate TSV connections. Placement of the first DRAM cell test pads 320 on the first vertical scribe line 301 and the second DRAM cell test pads 322 on the second vertical scribe line 303 of the DRAM wafer enables wafer probe testing for DRAM wafer yield evaluation and, hence, deficient DRAM wafers can be rejected sooner rather than later. In particular, the DRAM test pad arrangement beneficially improves DRAM yield by pre-forming the DRAM cell test/repair on the DRAM wafer before the 3D DRAM wafer bonding process. Additionally, a die test may involve statistically selecting DRAM dies among DRAM dies on the DRAM wafer to assess DRAM wafer yield, which saves test time and cost.

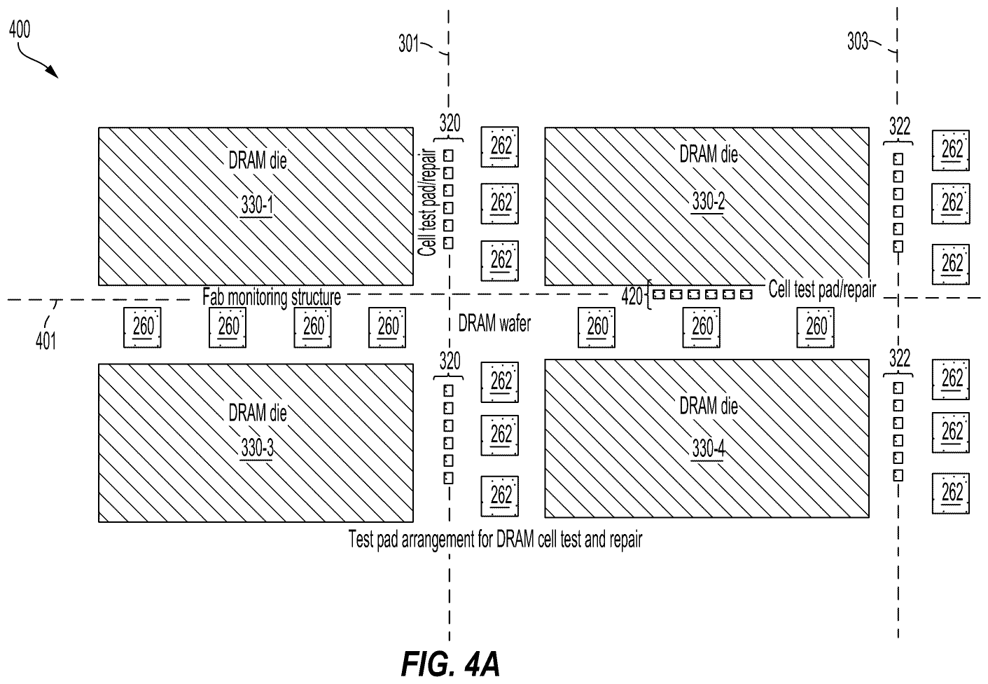

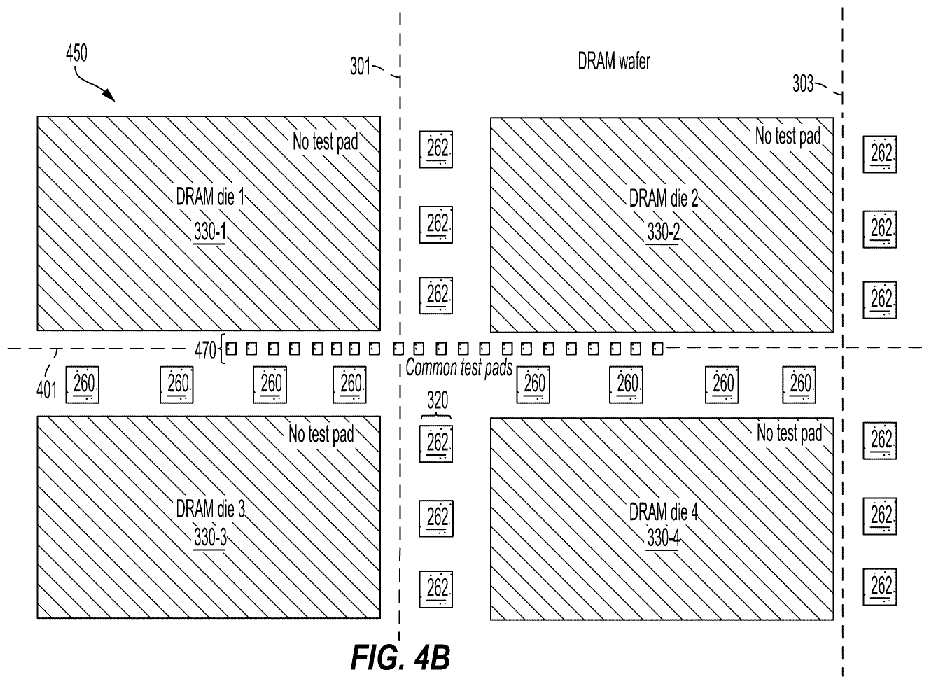

FIGS. 4A and 4B illustrate layout views of a memory test pad arrangement for memory cell testing and repair, according to various aspects of the present disclosure. The memory testing may include an electrical test and a functional test of the memory dies, as follows.

FIG. 4A illustrates a layout view 400 of a memory test pad arrangement for memory cell testing and repair, according to various aspects of the present disclosure. The layout view 400 of FIG. 4A is like the layout view 300 shown in FIG. 3 and is described using similar reference numbers. FIG. 4A further illustrates horizontal DRAM cell test pads 420 on a horizontal scribe line 401 of the DRAM wafer, according to various aspects of the present disclosure. According to various aspects of the present disclosure, the DRAM cell test and repair pads may be located vertically or horizontally on the DRAM wafer.

FIG. 4B illustrates a layout view 450 of a memory test pad arrangement for memory cell testing and repair, according to various aspects of the present disclosure. The layout view 450 of FIG. 4B is like the layout view 300 shown in FIG. 3 and is described using similar reference numbers. FIG. 4B further illustrates horizontal DRAM cell common test pads 470 on a horizontal scribe line 401 of the layout view 450 of the DRAM wafer, according to various aspects of the present disclosure. In this implementation, the horizontal DRAM cell common test pads 470 are located along a scribe line area proximate the horizontal scribe line 401 for reducing both time/cost and wafer bonding issues by providing wafer probe marks on standard memory test pads inside the DRAM dies 330 (e.g., 330-1, . . . , 330-4). In this example, the horizontal DRAM cell common test pads 470 along the horizontal scribe line 401 enable concurrent testing of the four of the DRAM dies 330 (e.g., 330-1, . . . , 330-4) to reduce time/cost.

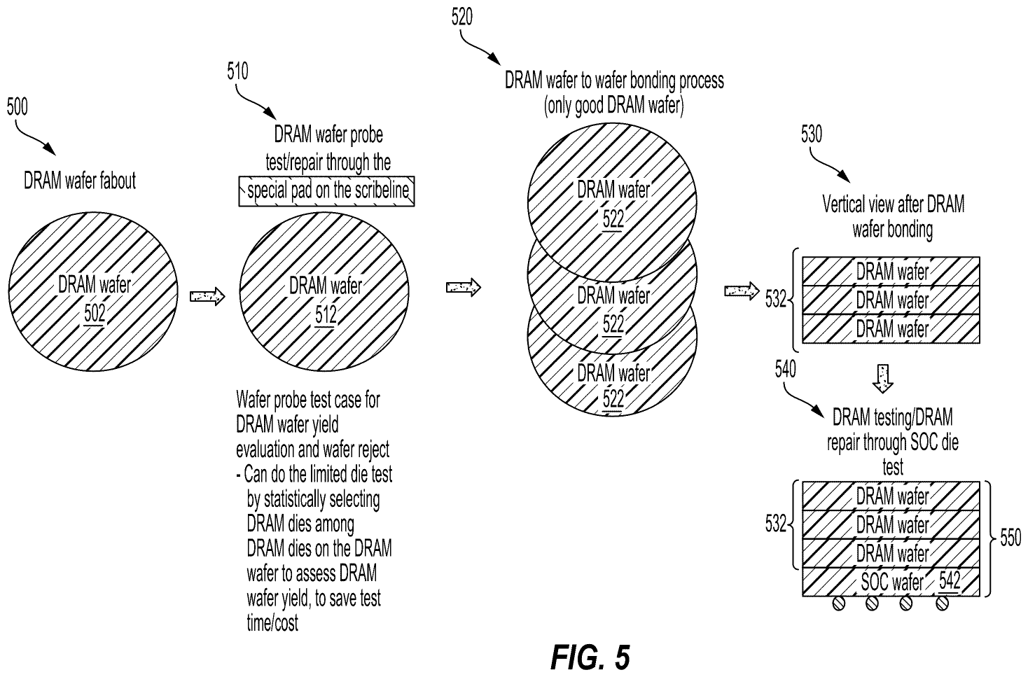

According to various aspects of the present disclosure, the DRAM cell test and repair pads may be located vertically or horizontally on the DRAM wafer before the 3D DRAM wafer bonding process, for example, as shown in FIG. 5.

FIG. 5 illustrates a process of forming dynamic random-access memory (DRAM) cell test and repair pads in three-dimensional (3D) stacked DRAM for improved yield, according to various aspects of the present disclosure. According to various aspects of the present disclosure, the DRAM wafer process is expanded to provide wafer acceptance testing (WAT) on DRAM wafers, as follows. At step 500, a DRAM wafer 502 is generated by a DRAM wafer fabrication output process, including DRAM test and repair pads in the scribe lines. At step 510, probing of a DRAM wafer 512 is performed using the DRAM test and repair pads in the scribe lines of the DRAM wafer 512. At step 510, the wafer probe test performs memory wafer yield evaluation and memory wafer rejection. Additionally, the wafer probe test utilizing the DRAM test and repair pads may perform tests on the DRAM dies on the DRAM wafer, such as electrical tests and functional tests of the DRAM dies. Furthermore, by probing the DRAM test and repair pads, a limited die test can be performed by statistically selecting DRAM dies among DRAM dies on the DRAM wafer 512 to assess DRAM wafer yield for saving both test time and cost.

At step 520, using the DRAM wafer probe test on DRAM test and repair pads in the scribe lines, verified DRAM wafers 522 are utilized for the wafer-to-wafer bonding to form a DRAM wafer stack 532 at step 530. At step 540, the DRAM wafer stack 532 is stacked on a system-on-chip (SoC) wafer 542 and bonded. The DRAM wafer stack 532 and the SoC wafer 542 are bonded to form a 3D stacked memory wafer 550, in which further DRAM testing and repair is performed through the SoC wafer 542, including performing memory electrical testing and functional testing. This process repairs DRAM cells in parallel with the DRAM wafer test and can reduce the test time/cost for the DRAM test/repair through the SoC wafer 542.

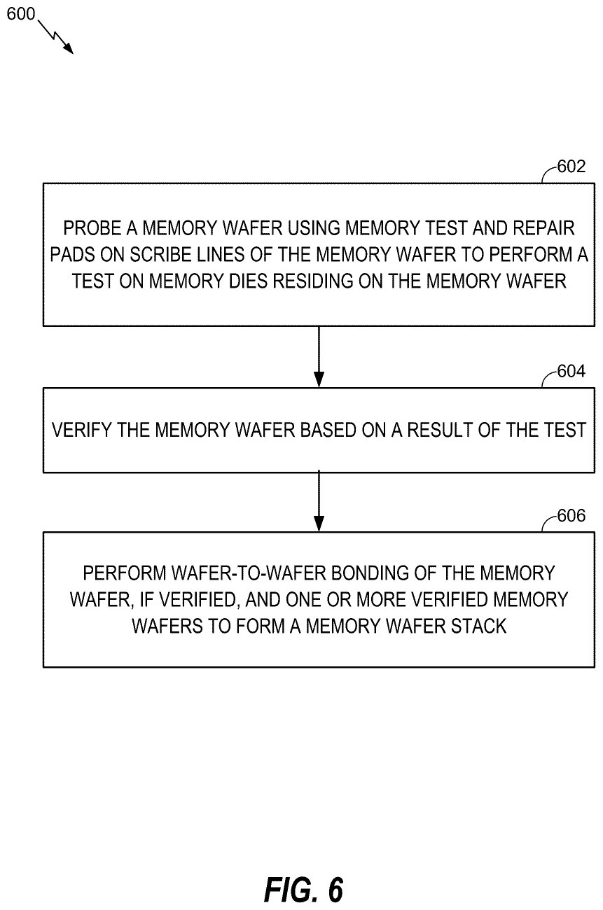

In some implementations, a set of wire connections are coupled between the horizontal DRAM cell test pads 420/the horizontal DRAM cell common test pads 470 and data DQ output pads as well as command connections of each memory cell array of the DRAM wafers 522. Following step 540, the 3D stacked memory wafer 550 is diced to form 3D stacked memory chips, such as the high-bandwidth 3D stacked memory chip 200, as shown in FIG. 2A. In this example, the set of wire connections is configured to couple to horizontal DRAM cell test pads 420 and/or the horizontal DRAM cell common test pads 470 along scribe lines between adjacent memory dies prior to dicing. Following the dicing, each of the set of wire connections distal from data DQ output pads as well as command connections of the memory cell arrays of the DRAM wafers 522 includes a wire stub portion exposed along an edge of the memory dies. A process of forming a DRAM cell test and repair pad in 3D stacked DRAM for improved yield is illustrated, for example, in FIG. 6.

FIG. 6 is a process flow diagram illustrating a method 600 for forming dynamic random-access memory (DRAM) cell test pads on scribe lines of a DRAM wafer, according to various aspects of the present disclosure. The method 600 begin at block 602, in which a memory wafer is probe using memory test and repair pads on scribe lines of the memory wafer to perform test on memory dies residing on the memory wafer. For example, as shown in FIG. 5, at step 500, a DRAM wafer 502 is generated by a DRAM wafer fabrication output process, including DRAM test and repair pads in the scribe lines. At step 510, probing of a DRAM wafer 512 is performed using the DRAM test and repair pads in the scribe lines of the DRAM wafer 512.

At block 604, the memory wafer is verify based on a result of the test. For example, as shown in FIG. 5, at step 510, the wafer probe test performs DRAM wafer yield evaluation and wafer rejection. Additionally, the wafer probe test utilizing the DRAM test and repair pads may perform tests on the DRAM dies on the DRAM wafer, such as electrical tests and functional tests of the DRAM dies. Furthermore, by probing the DRAM test and repair pads, a limited die test can be performed by statistically selecting DRAM dies among DRAM dies on the DRAM wafer 512 to assess DRAM wafer yield for saving both test time and cost.

At block 606, perform wafer-to-wafer bonding of the memory wafer, if verified, and one or more verified memory wafers to form a memory wafer stack. For example, as shown in FIG. 5, at step 520, using the DRAM wafer probe test on DRAM test and repair pads in the scribe lines, verified DRAM wafers 522 are utilized for the wafer-to-wafer bonding to form a DRAM wafer stack 532 at step 530.

In some implementations, DRAM test pads are provided on horizontal/vertical DRAM wafer scribe lines to enable DRAM cell functional testing. The special test pads are located on the scribe line, not on the actual DRAM die, and can reduce the wafer-to-wafer hybrid bonding issue on the actual DRAM die area by both metal pads and wafer test probe marks on the metal pads, by moving a test pad area on the actual DRAM die area to the scribe line area. By inserting the special test pads on the scribe line, the through silicon via (TSV) routing/TSV rule on the actual DRAM die area is not affected by the special test pad structure on the scribe line.

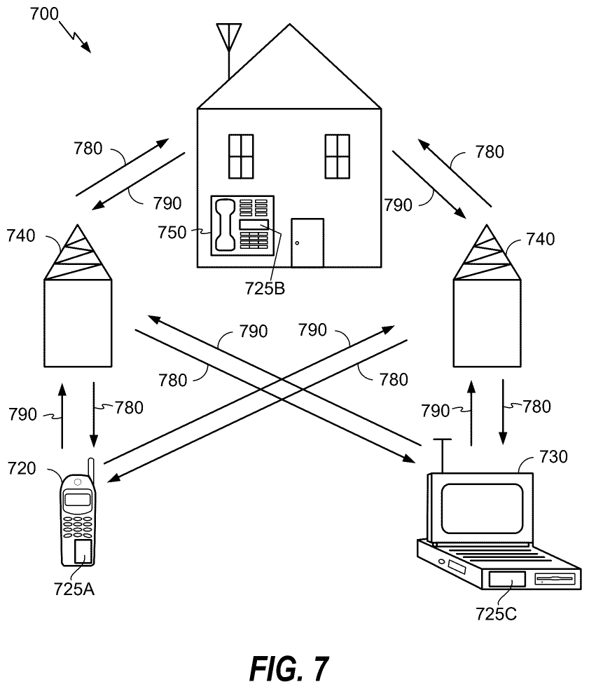

FIG. 7 is a block diagram showing an exemplary wireless communications system 700 in which a configuration of the disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include integrated circuit (IC) devices 725A, 725C, and 725B that include the disclosed dynamic random-access memory (DRAM) cell test and repair pads in three-dimensional (3D) stacked DRAM for improved yield. It will be recognized that other devices may also include the disclosed DRAM cell test and repair pads in 3D stacked DRAM for improved yield, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to aspects of the present disclosure, the disclosure is not limited to these exemplary illustrated units. Aspects of the present disclosure may be suitably employed in many devices, which include the disclosed vertical bank redundancy in 3D stacked DRAM for improved yield.

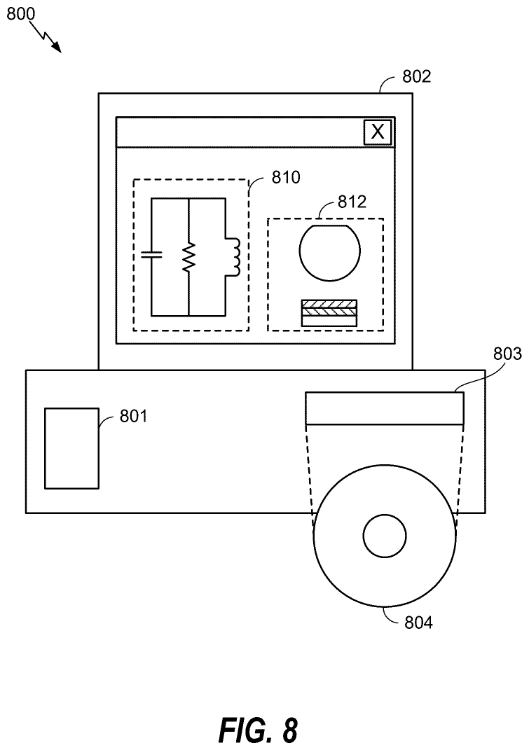

FIG. 8 is a block diagram illustrating a design workstation used for circuit, layout, and logic design of a semiconductor component, such as the vertical bank redundancy in three-dimensional (3D) stacked dynamic random-access memory (DRAM) for improved yield disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812, such as DRAM cell test and repair pads in 3D stacked DRAM for improved yield. A storage medium 804 is provided for tangibly storing the design of the circuit 810 or the IC component 812 (e.g., the DRAM cell test and repair pads). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

Implementation examples are described in the following numbered clauses:
1. A memory wafer, comprising:
a plurality of memory dies on the memory wafer; and
a plurality of wire connections at least partially within one of the plurality of memory dies, the plurality of wire connections configured to couple to a plurality of memory test and repair pads along at least one of a plurality of scribe lines between the one of the plurality of memory dies and adjacent memory dies.
2. The memory wafer of clause 1, in which the plurality of memory dies comprises a plurality of dynamic random-access memory (DRAM) dies.
3. The memory wafer of any of clauses 1 or 2, further comprising an integrated stack of a plurality of the memory wafer to form a memory wafer stack.
4. The memory wafer of clause 3, further comprising a system-on-chip (SoC) wafer supporting the memory wafer stack.
5. The memory wafer of any of clauses 1-4, in which the memory wafer comprises the plurality of memory test and repair pads along vertical scribe lines and/or horizontal scribe lines of the memory wafer.
6. A memory die, comprising:
a memory cell array; and
a plurality of wire connections to couple data DQ output pads and command connections of the memory cell array, in which each of the plurality of wire connections having a wire stub portion exposed along an edge of the memory die.
7. The memory die of clause 6, further comprising a base die supporting the memory die in a three-dimensional (3D) memory structure.
8. The memory die of clause 7, in which the base die comprises a system-on-chip (SoC) base die.
9. The memory die of clause 8, in which the memory die is integrated in a 3D stacked memory package on the SoC base die.
10. The memory die of any of clauses 6-9, in which the memory die comprises a dynamic random-access memory (DRAM) die.
11. The memory die of any of clauses 6-10, in which the memory cell array comprises a DRAM cell array.
12. A method for a memory cell repair test during fabrication, the method comprising:
probing a memory wafer using memory test and repair pads on scribe lines of the memory wafer to perform a test on memory dies residing on the memory wafer;
verifying the memory wafer based on a result of the test; and
performing wafer-to-wafer bonding of the memory wafer, if verified, and one or more verified memory wafers to form a memory wafer stack.
13. The method of clause 12, in which the test comprises an electrical test and a functional test of the memory dies.
14. The method of any of clauses 12 or 13, in which the test comprises statistically selecting memory dies on the memory wafer to perform a memory wafer yield evaluation and a memory wafer rejection.
15. The method of any of clauses 12-14, further comprising stacking the memory wafer stack on a system-on-chip (SoC) wafer.
16. The method of clause 15, further comprising performing memory testing and repair of the memory wafer stack through the SoC wafer.
17. The method of clause 16, further comprising forming a 3D stacked memory package from the memory wafer stack on the SoC wafer.
18. The method of any of clauses 12-17, in which the memory wafer comprises a plurality of dynamic random-access memory (DRAM) dies.
19. The method of any of clauses 12-18, in which the memory wafer comprises the memory test and repair pads along vertical scribe lines and/or horizontal scribe lines of the memory wafer.
20. The method of any of clauses 12-19, in which the memory test and repair pads comprise standard memory test pads along vertical scribe lines and/or horizontal scribe lines of the memory wafer configured to concurrently perform the test on the memory dies.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A memory wafer, comprising:
a plurality of memory dies on the memory wafer; and
a plurality of wire connections at least partially within one of the plurality of memory dies, the plurality of wire connections configured to couple to a plurality of memory test and repair pads along at least one of a plurality of scribe lines between the one of the plurality of memory dies and adjacent memory dies.

2. The memory wafer of claim 1, in which the plurality of memory dies comprises a plurality of dynamic random-access memory (DRAM) dies.

3. The memory wafer of claim 1, further comprising an integrated stack of a plurality of the memory wafer to form a memory wafer stack.

4. The memory wafer of claim 3, further comprising a system-on-chip (SoC) wafer supporting the memory wafer stack.

5. The memory wafer of claim 1, in which the memory wafer comprises the plurality of memory test and repair pads along vertical scribe lines and/or horizontal scribe lines of the memory wafer.

6. A memory die, comprising:
a memory cell array; and
a plurality of wire connections to couple data DQ output pads and command connections of the memory cell array, in which each of the plurality of wire connections having a wire stub portion exposed along an edge of the memory die.

7. The memory die of claim 6, further comprising a base die supporting the memory die in a three-dimensional (3D) memory structure.

8. The memory die of claim 7, in which the base die comprises a system-on-chip (SoC) base die.

9. The memory die of claim 8, in which the memory die is integrated in a 3D stacked memory package on the SoC base die.

10. The memory die of claim 6, in which the memory die comprises a dynamic random-access memory (DRAM) die.

11. The memory die of claim 6, in which the memory cell array comprises a DRAM cell array.

12. A method for a memory cell repair test during fabrication, the method comprising:
probing a memory wafer using memory test and repair pads on scribe lines of the memory wafer to perform a test on memory dies residing on the memory wafer;
verifying the memory wafer based on a result of the test; and
performing wafer-to-wafer bonding of the memory wafer, if verified, and one or more verified memory wafers to form a memory wafer stack.

13. The method of claim 12, in which the test comprises an electrical test and a functional test of the memory dies.

14. The method of claim 12, in which the test comprises statistically selecting memory dies on the memory wafer to perform a memory wafer yield evaluation and a memory wafer rejection.

15. The method of claim 12, further comprising stacking the memory wafer stack on a system-on-chip (SoC) wafer.

16. The method of claim 15, further comprising performing memory testing and repair of the memory wafer stack through the SoC wafer.

17. The method of claim 16, further comprising forming a 3D stacked memory package from the memory wafer stack on the SoC wafer.

18. The method of claim 12, in which the memory wafer comprises a plurality of dynamic random-access memory (DRAM) dies.

19. The method of claim 12, in which the memory wafer comprises the memory test and repair pads along vertical scribe lines and/or horizontal scribe lines of the memory wafer.

20. The method of claim 12, in which the memory test and repair pads comprise standard memory test pads along vertical scribe lines and/or horizontal scribe lines of the memory wafer configured to concurrently perform the test on the memory dies.
